(19) United States
(12) Patent Application Publication
(10) Pub. No.: US 2025/0120262 A1
(43) Pub. Date: Apr. 10, 2025

(54) DISPLAY DEVICE AND METHOD OF MANUFACTURING THE SAME

(71) Applicant: Samsung Display Co., LTD., Yongin-si (KR)

(72) Inventor: Hyun Eok SHIN, Yongin-si (KR)

(73) Assignee: Samsung Display Co., LTD., Yongin-si (KR)

(21) Appl. No.: 18/748,841

(22) Filed: Jun. 20, 2024

(30) Foreign Application Priority Data
Oct. 5, 2023 (KR) 10-2023-0132812

(51) Int. Cl. H10K 59/122; H10K 59/12; H10K 102/00

(52) U.S. Cl. CPC H10K 59/122; H10K 59/1201; H10K 2102/351

(57) ABSTRACT

A display device includes a partition wall disposed on a base layer; a light emitting part disposed adjacent to the partition wall; an upper light emitting part disposed on the partition wall; a first protective layer disposed on the light emitting part; and a second protective layer disposed on the first protective layer. The first protective layer entirely overlaps the light emitting part in a plan view, and the second protective layer does not overlap at least a portion of the light emitting part and at least a portion of the first protective layer in a plan view.

### CROSS-REFERENCE TO RELATED APPLICATION(S)

The application claims priority to and the benefits of Korean Patent Application No. 10-2023-0132812 under 35 U.S.C. § 119, filed Oct. 5, 2023, in the Korean Intellectual Property Office (KIPO), the entire contents of which are incorporated herein by reference.

### BACKGROUND

### 1. Technical Field

The disclosure relates to a display device and a method of manufacturing the same.

### 2. Description of the Related Art

As information technology develops, the importance of a display device as a connection medium between a user and information is being emphasized. Accordingly, research and development on the display device is continuously being conducted.

The display device may include a partition wall defining an area in which a light emitting part is disposed, and a protective layer covering at least a portion of the partition wall. In case that the protective layer is not properly formed in the display device, the risk of impurities (for example, moisture) penetrating into the display device from outside may increase.

### SUMMARY

A technical problem to be solved by the disclosure is to provide a display device having a protective structure that can stably cover a partition wall while reducing the risk of impurities penetrating from outside, and a method of manufacturing the same.

In order to solve the above technical problem, a display device according to an embodiment of the disclosure may include a partition wall disposed on a base layer; a light emitting part disposed adjacent to the partition wall; an upper light emitting part disposed on the partition wall; a first protective layer disposed on the light emitting part; and a second protective layer disposed on the first protective layer. The first protective layer may entirely overlap the light emitting part in a plan view, and the second protective layer may not overlap at least a portion of the light emitting part and at least a portion of the first protective layer in a plan view.

According to an embodiment, the first protective layer may include at least one of silicon nitride and silicon oxide, and the second protective layer may include an amorphous material.

According to an embodiment, the second protective layer may include at least one of amorphous silicon, silicon carbide, and silicon nitride hydrogen.

According to an embodiment, the display device may further include a pixel defining layer disposed on the base layer. The partition wall may be disposed on the pixel defining layer, and the light emitting part may include an area that does not overlap the second protective layer and the pixel defining layer in a plan view.

According to an embodiment, an end of each of the upper light emitting part, the first protective layer, and the second protective layer may coincide with each other.

According to an embodiment, at least a portion of the first protective layer may be bent to form an opening.

According to an embodiment, in a plan view, the opening and the second protective layer may overlap each other.

According to an embodiment, the opening formed by the first protective layer and the second protective layer may be in contact with each other.

According to an embodiment, the partition wall may include a first partition wall layer disposed on the pixel defining layer and a second partition wall layer disposed on the first partition wall layer, and the second partition wall layer may protrude further outward than the first partition wall layer.

According to an embodiment, the first partition wall layer may include aluminum (Al), and the second partition wall layer may include titanium (Ti).

According to an embodiment, the first protective layer and the second protective layer may expose at least a portion of the second partition wall layer.

According to an embodiment, a thickness of the first protective layer may be in a range of about 5000 Å to about 7000 Å, and a thickness of the second protective layer may be less than the thickness of the first protective layer.

In order to solve the above technical problem, a display device according to another embodiment of the disclosure may include a partition wall disposed on a base layer; a light emitting part disposed adjacent to the partition wall; an upper light emitting part disposed on the partition wall; a first protective layer disposed on the light emitting part; and a second protective layer disposed on the first protective layer. The first protective layer may entirely overlap the light emitting part in a plan view, and the second protective layer may include silicon nitride hydrogen.

According to an embodiment, the second protective layer may entirely overlap the light emitting part in a plan view.

According to an embodiment, a thickness of the first protective layer may be in a range of about 5000 Å to about 7000 Å, and a thickness of the second protective layer may be less than the thickness of the first protective layer.

In order to solve the above technical problem, a method of manufacturing a display device according to an embodiment of the disclosure may include forming a partition wall on a base layer, forming a light emitting part adjacent to the partition wall and an upper light emitting part on the partition wall, and forming a protective structure on the light emitting part. The forming of the protective structure on the light emitting part may include forming a first protective layer on the light emitting part; and forming a second protective layer on the first protective layer. The forming of the first protective layer on the light emitting part may include depositing a first base protective layer on the light emitting part so that a surface of the first base protective layer is bent to form an opening, and the forming of the second protective layer on the first protective layer may include depositing a second base protective layer including an amorphous material.

According to an embodiment, the first base protective layer may include at least one of silicon nitride and silicon oxide, the second base protective layer may include at least one of amorphous silicon, silicon carbide, and silicon nitride hydrogen, and the forming of the first protective layer on the light emitting part may include depositing the first base protective layer through a CVD (chemical vapor deposition) process.

According to an embodiment, in the forming of the protective structure on the light emitting part, a photoresist may be disposed on the second base protective layer, and the first base protective layer and the second base protective layer may be etched. The forming of the second protective layer on the first protective layer may include depositing the second base protective layer to cover a surface of the first base protective layer except for the opening, and the photoresist may include a first portion and a second portion having different thicknesses, and may be disposed on at least a portion of the second base protective layer.

According to an embodiment, the method of manufacturing the display device may further include forming a pixel defining layer on the base layer. The forming of the partition wall on the base layer may include forming the partition wall on the pixel defining layer, the first portion may overlap the upper light emitting part in a plan view, and the second portion may not overlap the pixel defining layer in a plan view.

According to an embodiment, the first base protective layer and the second base protective layer overlapping the first portion in a plan view may not be etched, and the second base protective layer overlapping the second portion in a plan view may be etched.

According to an embodiment, the first base protective layer may include at least one of silicon nitride and silicon oxide, the second base protective layer may include silicon nitride hydrogen, and in the forming of the protective structure on the light emitting part, a photoresist may be disposed on the first base protective layer so as to contact the first base protective layer.

According to an embodiment, the second base protective layer may be deposited to entirely overlap the light emitting part in a plan view.

### BRIEF DESCRIPTION OF THE DRAWINGS

FIG. 1 is a plan view schematically illustrating a display device according to an embodiment.

FIGS. 2 and 3 are schematic cross-sectional views of a display device according to an embodiment.

FIG. 4 is a schematic cross-sectional view of a light emitting element according to an embodiment.

FIGS. 5 and 6 are schematic cross-sectional views of a display device according to an embodiment.

FIG. 7 is a schematic block diagram schematically illustrating an electrical connection structure for a light emitting element according to an embodiment.

FIG. 8 is a flowchart schematically illustrating a method of manufacturing a display device according to an embodiment.

FIGS. 9 and 10 are schematic cross-sectional views schematically illustrating the method of manufacturing the display device according to an embodiment in each process step.

FIG. 11 is a flowchart schematically illustrating a step of forming a protective structure of FIG. 8.

FIGS. 12, 13, 14, and 15 are schematic cross-sectional views schematically illustrating a method of manufacturing a display device according to an embodiment in each process step.

FIG. 16 is a schematic cross-sectional view schematically illustrating a method of manufacturing a display device according to an embodiment in each process step.

FIG. 17 is a schematic block diagram of a display system according to an embodiment.

FIG. 18 is a schematic perspective view of the display system of FIG. 17 according to an embodiment.

### DETAILED DESCRIPTION OF THE EMBODIMENTS

As the disclosure allows for various changes and numerous embodiments, particular embodiments will be illustrated in the drawings and described in detail in the written description. However, this is not intended to limit the disclosure to particular modes of practice, and it is to be appreciated that all changes, equivalents, and substitutes that do not depart from the spirit and technical scope of the disclosure are encompassed in the disclosure.

It will be understood that, although the terms “first”, “second”, etc. may be used herein to describe various elements, these elements should not be limited by these terms. These terms are only used to distinguish one element from another element. For instance, a first element discussed below could be termed a second element without departing from the scope of the disclosure. Similarly, the second element could also be termed the first element. In the disclosure, the singular expressions are intended to include the plural expressions as well, unless the context clearly indicates otherwise.

It will be further understood that the terms “comprise”, “include”, “have”, etc. used in the disclosure, specify the presence of stated features, integers, steps, operations, elements, components, or combinations of them but do not preclude the presence or addition of one or more other features, integers, steps, operations, elements, components, or combinations thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The disclosure relates to a display device and a method of manufacturing the same. Hereinafter, the display device and the method of manufacturing the same according to embodiments of the disclosure will be described with reference to the attached drawings.

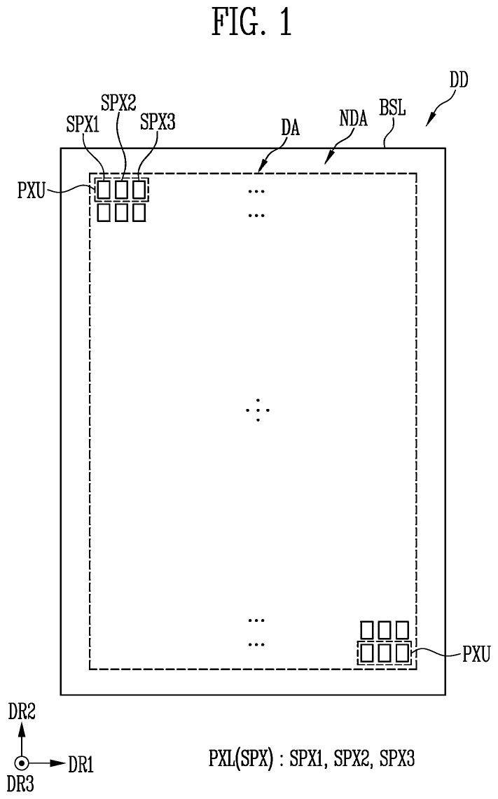

FIG. 1 is a plan view schematically illustrating a display device according to an embodiment.

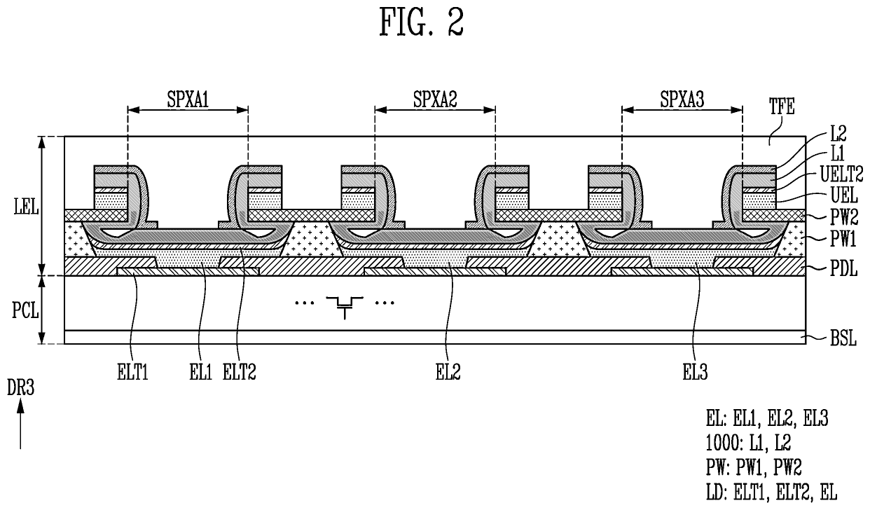

Referring to FIG. 1, a display device DD may be configured to emit light. The display device DD may include a light emitting element LD (see FIG. 2). According to an embodiment, the display device DD may be a device that displays a moving image or a still image. The display device DD may be used as a display screen for various products such as television, a laptop, a monitor, a billboard, and internet of things (IOT) as well as portable electronic devices such as a mobile phone, a smart phone, a tablet PC (personal computer), a smart watch, a watch phone, a mobile communication terminal, an electronic notebook, an e-book, a PMP (portable multimedia player), a navigation, and an UMPC (ultra mobile PC). However, the application field of the display device DD is not limited to specific examples.

The display device DD may have a rectangular flat plate shape having a short side in a first direction DR1 and a long side in a second direction DR2 that intersects the first direction DR1. A corner portion where the short side in the first direction DR1 and the long side in the second direction DR2 meet may be rounded to have a curvature or may be formed at a right angle. The planar shape of the display device DD is not limited to a square shape, and may be formed in a round shape such as a polygon, circle, or oval. The display device DD may be formed flat, but the disclosure is not limited thereto. For example, the display device DD may include curved portions formed at left and right ends and having a constant curvature or a changing curvature. In an embodiment, the display device DD may be flexible so that it can be bent, folded, or rolled.

In the disclosure, the first direction DR1 may be a row direction of a pixel PXL and may be a “horizontal” direction. The second direction DR2 may be a column direction of the pixel PXL. A third direction DR3 may be a display direction of the display device DD or a normal direction of a plane where a base layer BSL is disposed.

The display device DD may include a display area DA and a non-display area NDA. The non-display area NDA may be an area other than the display area DA. The non-display area NDA may surround at least a portion of the display area DA in a plan view.

The display area DA may be an area where the pixel PXL is disposed. The non-display area NDA may be an area where the pixel PXL is not disposed. A driving circuit unit, wirings, and pads connected to the pixel PXL of the display area DA may be disposed in the non-display area NDA.

According to an embodiment, the pixel PXL (or sub-pixels SPX) may include a first sub-pixel SPX1, a second sub-pixel SPX2, and a third sub-pixel SPX3. At least one first sub-pixel SPX1, at least one second sub-pixel SPX2, and at least one third sub-pixel SPX3 may form one pixel unit PXU capable of emitting light of various colors. FIG. 1 shows an embodiment in which each pixel PXL includes three sub-pixels SPX1, SPX2, and SPX3, for example, the first sub-pixel SPX1, the second sub-pixel SPX2, and the third sub-pixel SPX3, but the disclosure is not limited thereto.

According to an embodiment, the pixel PXL (or sub-pixels SPX) may be arranged in a stripe or PENTILE™ arrangement structure. However, the disclosure is not necessarily limited thereto.

The first sub-pixel SPX1 may emit first light, the second sub-pixel SPX2 may emit second light, and the third sub-pixel SPX3 may emit third light. In an embodiment, the first light may be light in a red wavelength band, the second light may be light in a green wavelength band, and the third light may be light in a blue wavelength band. The red wavelength band may be a wavelength band in a range of approximately 600 nm to approximately 750 nm, the green wavelength band may be a wavelength band in a range of approximately 480 nm to approximately 560 nm, and the blue wavelength band may be a wavelength band in a range of approximately 370 nm to approximately 460 nm, but the disclosure is not limited thereto.

Each of the first sub-pixel SPX1, the second sub-pixel SPX2, and the third sub-pixel SPX3 may include an inorganic light emitting element including an inorganic semiconductor or an organic light emitting diode (OLED) as a light emitting element that emits light. Although the disclosure is not limited to specific embodiments, for convenience of description, an embodiment in which each of the first sub-pixel SPX1, the second sub-pixel SPX2, and the third sub-pixel SPX3 includes an organic light emitting element will be described below.

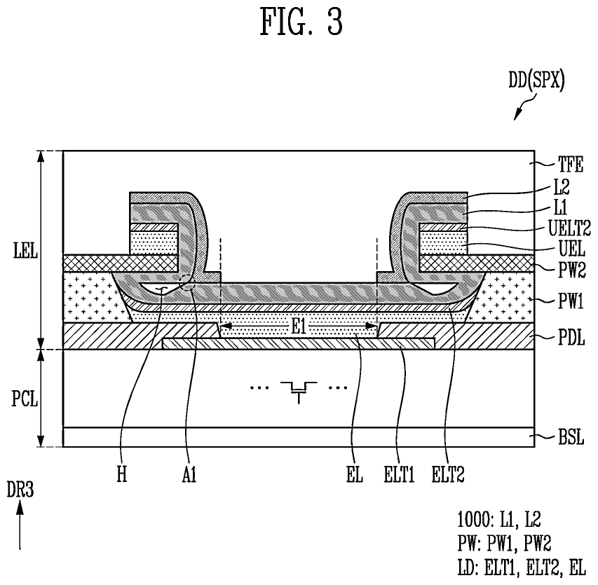

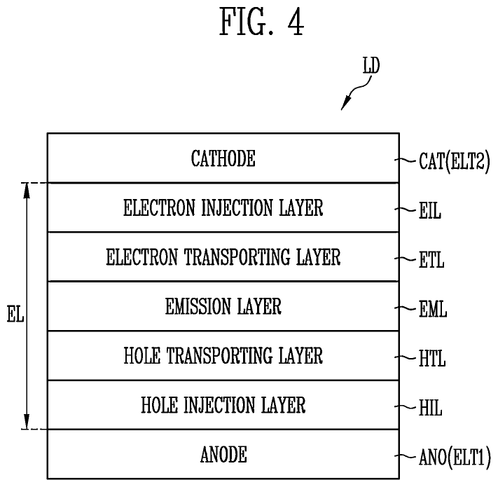

FIGS. 2 and 3 are schematic cross-sectional views of a display device according to an embodiment. FIG. 3 is a schematic cross-sectional view enlarging an area of FIG. 2. FIG. 3 may be a schematic cross-sectional view of one of the sub-pixels SPX disposed on the base layer BSL of FIG. 1. FIG. 4 is a schematic cross-sectional view of a light emitting element according to an embodiment.

Referring to FIGS. 2 to 4, the display device DD may include a pixel circuit layer PCL and a light emitting element layer LEL.

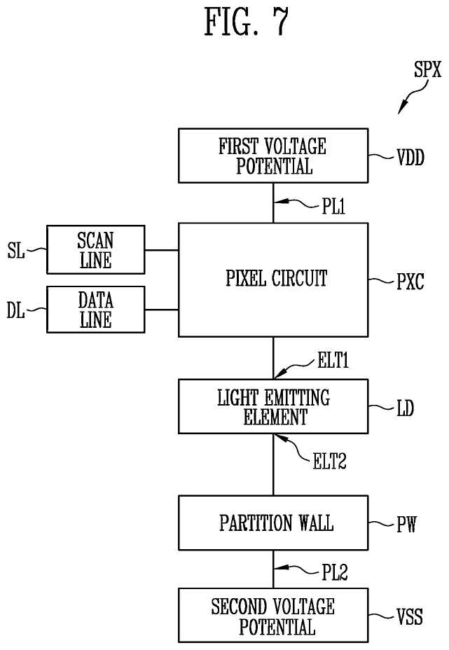

The pixel circuit layer PCL may be a layer including a pixel circuit PXC (see FIG. 7) for driving light emitting elements LD. The pixel circuit layer PCL may include a base layer BSL, conductive layers forming pixel circuits, and insulating layers disposed between the conductive layers.

According to an embodiment, the pixel circuit PXC may include circuit elements (for example, a driving transistor and the like) and may be electrically connected to the light emitting elements LD to provide electrical signals so that the light emitting elements LD emit light.

The light emitting element layer LEL may be disposed on the pixel circuit layer PCL. According to an embodiment, the light emitting element layer LEL may include a pixel defining layer PDL, a partition wall PW, a light emitting element LD, a protective structure 1000, and an encapsulation layer TFE.

The light emitting element LD may be disposed on the pixel circuit layer PCL (or the base layer BSL). According to an embodiment, the light emitting element LD may include a first electrode ELT1, a light emitting part EL, and a second electrode ELT2.

According to an embodiment, the light emitting part EL may be disposed in an area (for example, a first sub-pixel area SPXA1, a second sub-pixel area SPXA2, or a third sub-pixel area SPXA3 shown in FIG. 2) defined by the pixel defining layer PDL and the partition wall PW. The light emitting part EL may be disposed between partition walls PW. The light emitting part EL may be disposed adjacent to the partition wall PW. The light emitting part EL may include a first light emitting part EL1 for forming the first sub-pixel SPX1 emitting light of a first color, a second light emitting part EL2 for forming the second sub-pixel SPX2 emitting light of a second color, and a third light emitting part EL3 for forming the third sub-pixel SPX3 emitting light of a third color.

A side of the light emitting part EL may be electrically connected to the first electrode ELT1, and another side of the light emitting part EL may be electrically connected to the second electrode ELT2.

The first electrode ELT1 may be an anode electrode ANO for the light emitting part EL, and the second electrode ELT2 may be a cathode electrode CAT for the light emitting part EL. According to an embodiment, the first electrode ELT1 and the second electrode ELT2 may include a conductive material. For example, the first electrode ELT1 may include a conductive material having reflective properties, and the second electrode ELT2 may include a transparent conductive material, but the disclosure is not necessarily limited thereto. In another embodiment, the first electrode ELT1 may be a cathode electrode CAT for the light emitting part EL, and the second electrode ELT2 may be an anode electrode ANO for the light emitting part EL.

The light emitting part EL may have a multilayer thin film structure including a light generation layer (for example, an emission layer EML). The light emitting part EL may have a hole injection layer HIL that injects holes, a hole transporting layer HTL that has excellent hole transport properties and suppresses the movement of electrons that are not combined in the emission layer EML to increase the chance of recombination of holes and electrons, the emission layer EML that emits light by recombination of injected electrons and holes, an electron transporting layer ETL to readily transport electrons to the emission layer, and an electron injection layer EIL that injects electrons. The light emitting part EL may emit light based on electrical signals provided from the anode electrode ANO (for example, the first electrode ELT1) and the cathode electrode CAT (for example, the second electrode ELT2).

The pixel defining layer PDL may be disposed on the pixel circuit layer PCL. The pixel defining layer PDL may define the location where the light emitting part EL is arranged. At least some portions of the pixel defining layer PDL may be spaced apart from each other with light emitting parts EL interposed the portions of the pixel defining layer PDL. At least a portion of the pixel defining layer PDL may be disposed on the first electrode ELT1. The pixel defining layer PDL may be disposed adjacent to the first electrode ELT1. At least a portion of the pixel defining layer PDL may expose at least a portion of the first electrode ELT1. At least a portion of the pixel defining layer PDL may overlap the first electrode ELT1 in a plan view. The pixel defining layer PDL may cover an end of the first electrode ELT1.

The pixel defining layer PDL may include an inorganic material. For example, the pixel defining layer PDL may include at least one of silicon nitride (SiNₓ), silicon oxide (SiOₓ), silicon oxynitride (SiOₓN_{y}), and aluminum oxide (AlOₓ). However, the disclosure is not limited thereto. The pixel defining layer PDL may include an organic material. For example, the pixel defining layer PDL may include at least one of an acryl resin, an epoxy resin, a phenol resin, a polyamide resin, and a polyimide resin.

The partition walls PW may be disposed on the pixel defining layer PDL. The partition walls PW may be disposed between the light emitting parts EL. The partition walls PW may be disposed between or at boundaries of adjacent sub-pixels SPX1, SPX2, and SPX3 to define the first sub-pixel area SPXA1, the second sub-pixel area SPXA2, and the third sub-pixel area SPXA3.

The partition wall PW may include a multi-layered structure. According to an embodiment, the partition wall PW may include a double layer structure. For example, the partition wall PW may include a first partition wall layer PW1 and a second partition wall layer PW2. However, the disclosure is not necessarily limited thereto. Hereinafter, an embodiment that the partition wall PW has a double layer structure including a first partition wall layer PW1 and a second partition wall layer PW2 will be described.

The first partition wall layer PW1 and the second partition wall layer PW2 may be stacked in a thickness direction (for example, the third direction DR3) of the base layer BSL. For example, the first partition wall layer PW1 may be disposed on the pixel defining layer PDL. The second partition wall layer PW2 may be disposed on the first partition wall layer PW1.

The first partition wall layer PW1 may have a width narrower than a width of the second partition wall layer PW2. For example, the second partition wall layer PW2 may protrude further outward than the first partition wall layer PW1 in the first direction DR1 or the second direction DR2. For example, the partition wall PW may have a ‘T’ shaped structure in a cross-sectional view. For example, the partition wall PW may form a tip structure in which the first partition wall layer PW1 is recessed further inward than the second partition wall layer PW2. As the partition wall PW has the tip structure, the light emitting part EL may not cover at least a portion of the side surface of the first partition wall layer PW1.

When depositing an organic material to form the light emitting parts EL, the light emitting parts EL may be separated from each other due to the tip structure of the partition PW, and the sub-pixels SPX1, SPX2, and SPX3 may be separated from each other. For example, the light emitting part EL may be divided into the first light emitting part EL1, the second light emitting part EL2, and the third light emitting part EL3.

The first partition wall layer PW1 may have a thickness greater than a thickness of the second partition wall layer PW2. For example, since the first partition wall layer PW1 is formed thicker than the second partition wall layer PW2, when forming the light emitting part EL, the light emitting part EL may cover a side surface of the first partition wall layer PW1 and not cover a side surface of the second partition wall layer PW2.

In the disclosure, the width may be defined based on a direction in which the plane in which the base layer BSL is disposed extends (for example, the first direction DR1 or the second direction DR2), and the thickness may be defined based on the thickness direction (for example, the third direction DR3) of the base layer BSL.

The partition wall PW may include a metal material. For example, the partition wall PW may include at least one of gold (Au), silver (Ag), aluminum (Al), molybdenum (Mo), chromium (Cr), titanium (Ti), nickel (Ni), neodymium (Nd), copper (Cu), and platinum (Pt).

According to an embodiment, the first partition wall layer PW1 may include aluminum (Al). According to an embodiment, the second partition wall layer PW2 may include titanium (Ti). However, the disclosure is not limited thereto.

According to an embodiment, the display device DD may further include an upper light emitting part UEL. The upper light emitting part UEL may be disposed on the partition wall PW. In an embodiment of the disclosure, the upper light emitting part UEL and the light emitting part EL that emits light may be formed in a same deposition process. The upper light emitting part UEL may be disposed on the second partition wall layer PW2. The upper light emitting part UEL may cover at least a portion of the second partition wall layer PW2. The upper light emitting part UEL may expose at least a portion of the second partition wall layer PW2.

According to an embodiment, the display device DD may further include an upper second electrode UELT2. The upper second electrode UELT2 may be disposed on the upper light emitting part UEL. In an embodiment of the disclosure, the upper second electrode UELT2 and the second electrode ELT2 disposed between the partition walls PW may be formed in a same deposition process. The upper second electrode UELT2 may be disposed on the second partition wall layer PW2. The upper second electrode UELT2 may overlap at least a portion of the second partition wall layer PW2 in a plan view. The upper light emitting part UEL may expose at least a portion of the second partition wall layer PW2.

The protective structure 1000 may be disposed on the second electrode ELT2. The protective structure 1000 may protect the second electrode ELT2, components disposed below the second electrode ELT2, and at least a portion of the partition wall PW.

The protective structure 1000 may include a multi-layered structure. For example, the protective structure 1000 may have a double layer structure including a first protective layer L1 and a second protective layer L2. However, the disclosure is not limited thereto. Hereinafter, an embodiment that the protective structure 1000 has a double layer structure including the first protective layer L1 and the second protective layer L2 will be described.

The first protective layer L1 may be disposed on the second electrode ELT2. The first protective layer L1 may be in contact with the second electrode ELT2. At least a portion of the first protective layer L1 may be in contact with the second electrode ELT2, and at least another portion of the first protective layer L1 may be in contact with the upper second electrode UELT2. At least a portion of the first protective layer L1 may cover side surfaces of the first partition wall layer PW1, the second partition wall layer PW2, the upper light emitting part UEL, and the upper second electrode UELT2.

The first protective layer L1 may entirely overlap the light emitting part EL in a plan view. The first protective layer L1 may not be disposed on at least a portion of the second partition wall layer PW2. The first protective layer L1 may not be in contact with at least a portion of the second partition wall layer PW2. The first protective layer L1 may expose at least a portion of the second partition wall layer PW2.

The thickness of the first protective layer L1 may be in a range of about 5000 Å to about 7000 Å. However, the disclosure is not limited thereto. The thickness of the first protective layer L1 may vary.

According to an embodiment, the first protective layer L1 may include an inorganic material. For example, the first protective layer L1 may include at least one of silicon nitride (SiNₓ) (x is a natural number from 1 to 5), and silicon oxide (SiOₓ) (x is a natural number from 1 to 5).

Experimentally, in case that the first protective layer L1 includes at least one of silicon nitride (SiNₓ) and silicon oxide (SiOₓ), when depositing the first protective layer L1, a surface of the first protective layer L1 may be bent. At least a portion of a surface of the first protective layer L1 may be an inclined surface. A surface of the first protective layer L1 may be bent to define an opening H. For example, a surface of the first protective layer L1 may be bent to form an area A1 where surfaces of the first protective layer L1 contact with each other, and the opening H may be formed. The opening H may be defined by the surface of the first protective layer L1. The opening H may be an area where a discontinuous surface (for example, a seam area) is formed as the first protective layer L1 is bent. The opening H may be disposed adjacent to the first partition wall layer PW1. The first protective layer L1 interposed between the opening H and the first partition wall layer PW1.

The second protective layer L2 may be disposed on the first protective layer L1. The second protective layer L2 may be in contact with the first protective layer L1. The second protective layer L2 may expose at least a portion of the first protective layer L1. The second protective layer L2 may not overlap at least a portion of the first protective layer L1 in a plan view. The second protective layer L2 may overlap the opening H in a plan view. The second protective layer L2 may cover the area A1 where the surfaces of the first protective layer L1 contact with each other. For example, the second protective layer L2 may be in contact with a portion where the surfaces of the first protective layer L1 contact with each other. For example, the second protective layer L2 may be in contact with the opening H.

The second protective layer L2 may overlap the pixel defining layer PDL in a plan view. The second protective layer L2 may not overlap at least a portion of the light emitting part EL in a plan view. For example, at least a portion of the light emitting part EL that does not overlap the pixel defining layer PDL and the second protective layer L2 may not overlap with each other in a plan view.

The second protective layer L2 may not be disposed on at least a portion of the second partition wall layer PW2. The second protective layer L2 may not be in contact with at least a portion of the second partition wall layer PW2. The second protective layer L2 may expose at least a portion of the second partition wall layer PW2.

An end of the second protective layer L2 and an end of the first protective layer L1 may coincide with each other. An end of the second protective layer L2 and an end of each of the upper second electrode UELT2 and the upper light emitting part UEL may coincide with each other. An end of each of the second protective layer L2, the first protective layer L1, the upper second electrode UELT2, and the upper light emitting part UEL may overlap each other in a plan view. Edges of the second protective layer L2, the first protective layer L1, the upper second electrode UELT2, and the upper light emitting part UEL may correspond to each other.

As the display device DD according to embodiments of the disclosure includes the second protective layer L2, the risk of impurities (for example, moisture) penetrating into the display device DD may be reduced. In a conventional display device, a protective layer disposed on the second electrode ELT2 includes only the first protective layer L1. Accordingly, moisture may penetrate into the opening H formed by the first protective layer L1. On the other hand, in the display device DD according to embodiments of the disclosure, as the second protective layer L2 covers the area A1 where the surfaces of the first protective layer L1 contact with each other, the risk of impurities (for example, moisture) penetrating into the opening H may be reduced.

The thickness of the second protective layer L2 may be less than the thickness of the first protective layer L1. For example, the thickness of the second protective layer L2 may be in a range of about 500 Å to about 1500 Å. However, the disclosure is not limited thereto. The thickness of the second protective layer L2 may vary.

The second protective layer L2 may be an amorphous thin film layer. The second protective layer L2 may include an amorphous material. For example, the second protective layer L2 may include amorphous silicon. However, the disclosure is not limited thereto. The second protective layer L2 may include various materials capable of forming an amorphous thin film layer. For example, the second protective layer L2 may include silicon carbide (SiC). For example, the second protective layer L2 may include silicon nitride hydrogen (SiNₓH_{y}) (x is a natural number from 1 to 5, and y is a natural number from 1 to 5).

In case that the second protective layer L2 includes amorphous silicon, the extinction coefficient of the second protective layer L2 may be greater than or equal to about 0.1. In the disclosure, the extinction coefficient may be a molecular extinction coefficient (k). The second protective layer L2 may absorb light to reduce scattering of external light incident on the partition wall PW. The second protective layer L2 may block light to reduce reflection of external light.

As the second protective layer L2 exposes at least a portion of the first protective layer L1, light emitted from the light emitting part EL may be emitted into an emission area E1. The emission area E1 may be an area where light can be emitted to the outside of the display device DD. The emission area E1 may be an area of the light emitting part EL that does not overlap the pixel defining layer PDL. The second protective layer L2 may not be disposed in an area that overlaps the emission area E1. Accordingly, in the area overlapping the emission area E1, the light emitted from the light emitting part EL may not be blocked by the second protective layer L2.

The encapsulation layer TFE may be disposed on the light emitting element LD (for example, the second electrode ELT2). The encapsulation layer TFE may cancel out a step difference caused by the light emitting element LD and the pixel defining film PDL. The encapsulation layer TFE may include multiple insulating layers that cover the protective structure 1000 and the light emitting element LD. According to an embodiment, the encapsulation layer TFE may have a structure in which inorganic layers and organic layers are alternately stacked each other. According to an embodiment, the encapsulation layer TFE may be a thin film encapsulation layer.

According to an embodiment, although not shown in the drawings, the display device DD may further include an optical functional layer, an overcoat layer, and a cover window disposed on the encapsulation layer TFE. However, the structure of the display device DD is not necessarily limited to the above-described embodiments.

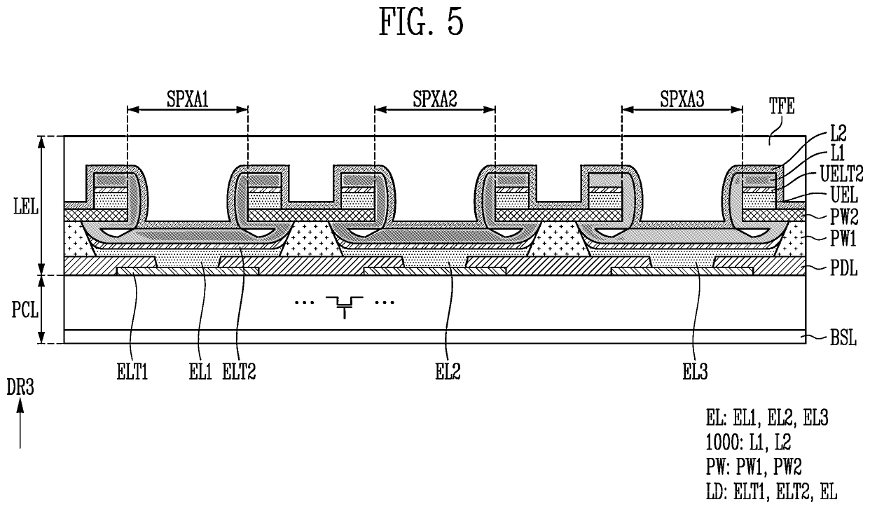

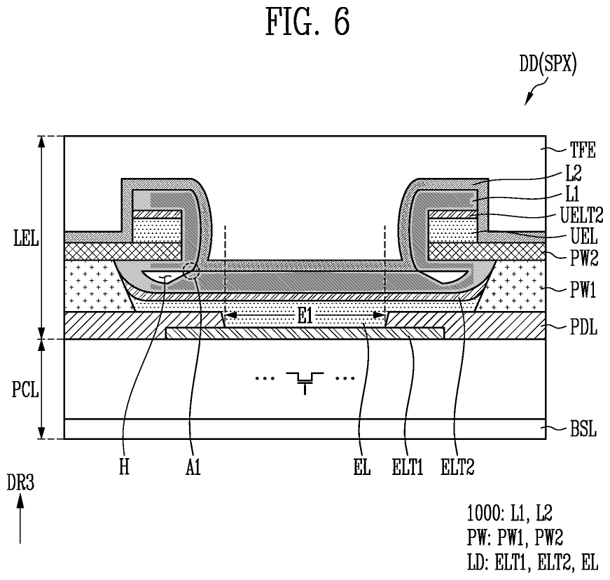

FIGS. 5 and 6 are schematic cross-sectional views of a display device according to an embodiment. FIG. 6 is a schematic cross-sectional view enlarging an area of FIG. 5. FIG. 6 may be a schematic cross-sectional view of one of the sub-pixels SPX disposed on the base layer BSL of FIG. 1. Hereinafter, the display device DD according to an embodiment will be described with reference to FIGS. 5 and 6.

Compared to the embodiment of FIGS. 2 and 3, the embodiment of FIGS. 5 and 6 may be different in that the second protective layer L2 entirely covers the first protective layer L1 in the emission area E1.

The second protective layer L2 may be disposed on the first protective layer L1. The second protective layer L2 may entirely cover the first protective layer L1 in the emission area E1. The second protective layer L2 may entirely overlap the first protective layer L1 in the emission area E1 in a plan view.

The second protective layer L2 may be disposed on at least a portion of the second partition wall layer PW2. The second protective layer L2 may be in contact with at least a portion of the second partition wall layer PW2. The second protective layer L2 may cover at least a portion of the second partition wall layer PW2. The second protective layer L2 may be in contact with the upper light emitting part UEL and the upper second electrode UELT2.

The second protective layer L2 may entirely cover the light emitting part EL in a plan view. The second protective layer L2 may entirely overlap the light emitting part EL in a plan view. At least a portion of the light emitting part EL that does not overlap the pixel defining layer PDL and the second protective layer L2 may overlap each other in a plan view. The second protective layer L2 and the emission area E1 may overlap each other.

The second protective layer L2 of the display device DD according to an embodiment may include silicon nitride hydrogen (SiNₓH_{y}). Experimentally, silicon nitride hydrogen (SiNₓH_{y}) may have a relatively low extinction coefficient compared to amorphous silicon. Accordingly, even in case that the second protective layer L2 is deposited to entirely cover the light emitting part EL, in the emission area E1, the light emitted from the light emitting part EL may not be blocked by the second protective layer L2. Accordingly, even in case that the second protective layer L2 entirely overlaps the light emitting part EL, the light emitting efficiency of the display device DD may not be reduced.

FIG. 7 is a schematic block diagram schematically illustrating an electrical connection structure for a light emitting element according to an embodiment. For example, FIG. 7 may show an electrical connection structure including the pixel circuit PXC corresponding to each sub-pixel SPX.

Referring to FIG. 7, the sub-pixel SPX may include a pixel circuit PXC configured to drive the light emitting element LD.

The pixel circuit PXC may include one or more circuit elements. For example, the pixel circuit PXC may include transistors and a storage capacitor. For example, the pixel circuit PXC may include a driving transistor, a switching transistor, and a storage capacitor. However, the disclosure is not necessarily limited thereto.

The pixel circuit PXC may be electrically connected to a scan line SL and a data line DL. The scan line SL may supply a scan signal to the pixel circuit PXC. According to an embodiment, the scan line SL may be electrically connected to a gate electrode of the switching transistor of the pixel circuit PXC. The light emitting element LD may be configured to emit light corresponding to a data signal provided from the data line DL.

The pixel circuit PXC may be electrically connected to a first power source line PL1 and a second power source line PL2. For example, the first electrode ELT1 of the light emitting element LD may be electrically connected to the pixel circuit PXC and the first power source line PL1, and the second electrode ELT2 of the light emitting element LD may be electrically connected to the second power source line PL2. According to an embodiment, the second power source line PL2 may be formed in the pixel circuit layer PCL in the display area DA. In another embodiment, the second power source line PL2 may be disposed in the non-display area NDA. Accordingly, the second power source line PL2 may be configured to supply a second power source to the light emitting element LD.

A power source of the first power source line PL1 and a power source of the second power source line PL2 may have different potentials. For example, the power source of the first power source line PL1 may be a high-potential pixel power source supplied from a first voltage potential VDD, and the power source of the second power source line PL2 may be a low-potential pixel power source supplied from a second voltage potential VSS. A potential difference between the power source of the first power source line PL1 and the power source of the second power source line PL2 may be set to be higher than a threshold voltage of the light emitting elements LD.

The first power source line PL1 may be electrically connected to the pixel circuit PXC (for example, the driving transistor). The second power source line PL2 may be electrically connected to the cathode electrode (for example, the second electrode ELT2) of the light emitting element LD.

According to an embodiment, the second power source line PL2 may be electrically connected to the second electrode ELT2 through the partition wall PW. For example, the partition wall PW may electrically connect the second electrode ELT2 and the second power source line PL2.

Each light emitting element LD may be connected in a forward direction between the first power source line PL1 and the second power source line PL2 and form each effective light source. These effective light sources may be gathered together to form the light emitting elements LD of the sub-pixels SPX.

The light emitting elements LD may emit light with a luminance corresponding to a driving current supplied through the pixel circuit PXC. During each frame period, the pixel circuit PXC may supply a driving current corresponding to the data signal to the light emitting element LD. The light emitting element LD may emit light with a luminance corresponding to the driving current.

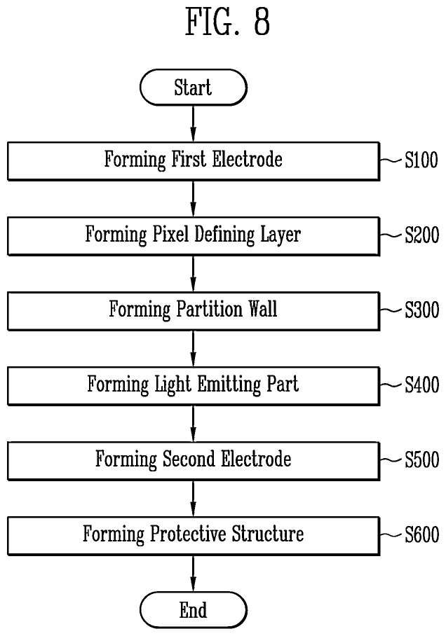

Hereinafter, a method of manufacturing the display device DD will be described with reference to FIGS. 8 to 15.

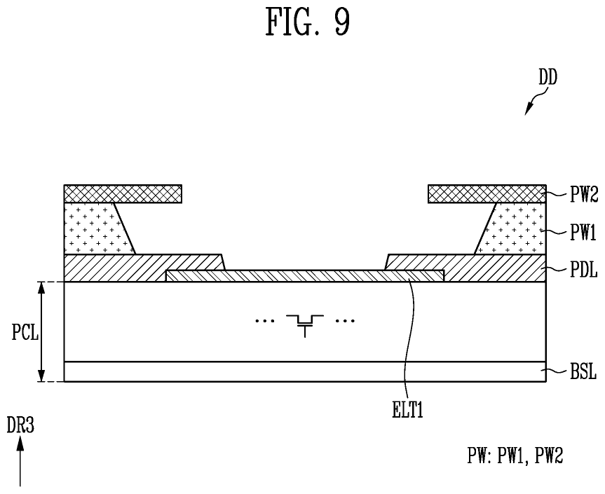

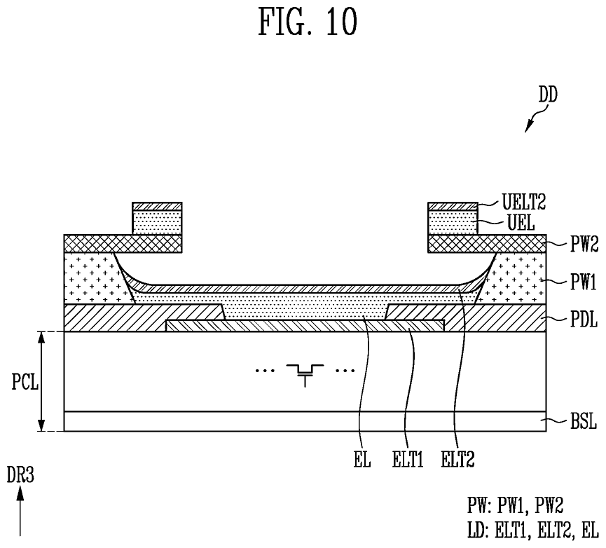

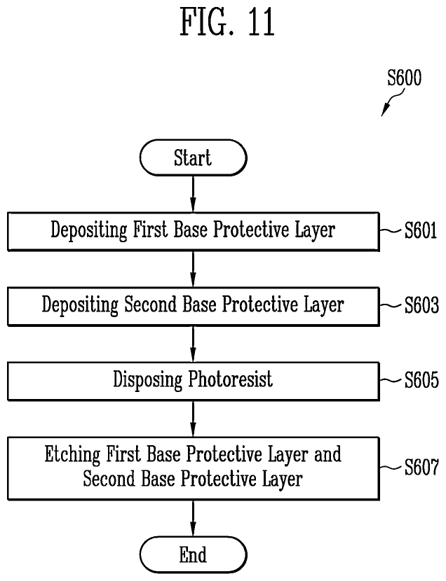

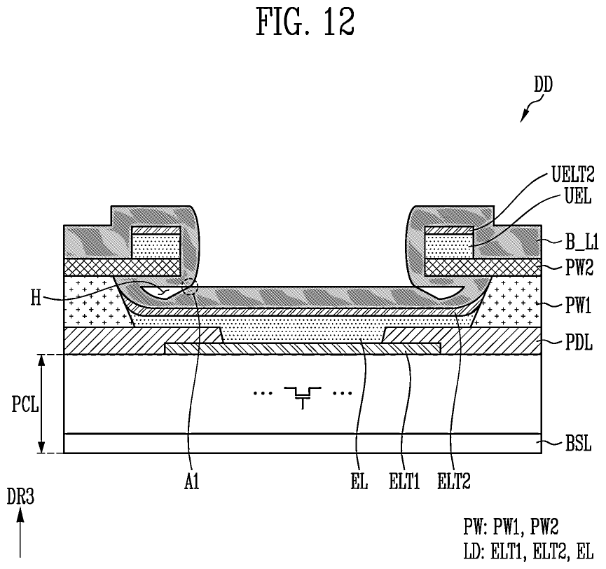

FIG. 8 is a flowchart schematically illustrating a method of manufacturing a display device according to an embodiment. FIGS. 9 and 10 are schematic cross-sectional views schematically illustrating the method of manufacturing the display device according to an embodiment in each process step. FIG. 11 is a flowchart schematically illustrating a step of forming a protective structure of FIG. 8. FIGS. 12, 13, 14, and 15 are schematic cross-sectional views schematically illustrating a method of manufacturing a display device according to an embodiment in each process step.

Referring to FIG. 8, a method of manufacturing the display device DD may include forming a first electrode (S100), forming a pixel defining layer (S200), forming a partition wall (S300), forming a light emitting part (S400), forming a second electrode (S500), and forming a protective structure (S600).

Referring to FIG. 9, before the forming of the first electrode (S100), the pixel circuit layer PCL including the pixel circuit PXC for driving the light emitting elements LD may be formed on the base layer BSL. The pixel circuit layer PCL may be formed to include conductive layers and insulating layers disposed between the conductive layers.

According to an embodiment, components disposed on the base layer BSL may be formed through a general patterning process (for example, a photolithography process and the like) using a mask.

In the forming of the first electrode (S100), the first electrode ELT1 may be formed on the pixel circuit layer PCL. According to an embodiment, the first electrode ELT1 may be deposited on the pixel circuit layer PCL and etched to expose at least a portion of the pixel circuit layer PCL.

In the disclosure, as a process for depositing components of the display device DD, one or more of a chemical vapor deposition (CVD) process and an atomic layer deposition (ALD) process may be used. In the disclosure, as an etching process, one or more of a wet etching process and a dry etching process may be used. However, the disclosure is not limited to specific examples.

Although not shown in the drawings, according to an embodiment, after forming of the first electrode ELT1, the first electrode ELT1 may be electrically connected to a driving transistor through a hole penetrating a protective layer of the pixel circuit layer PCL. In the forming of the pixel defining layer (S200), the pixel defining layer PDL may be formed on the pixel circuit layer PCL. The pixel defining layer PDL may be deposited on the pixel circuit layer PCL and the first electrode ELT1, and the pixel defining layer PDL may be etched to expose at least a portion of the first electrode ELT1. The pixel defining layer PDL may be etched to overlap the remaining portion of the first electrode ELT1 in a plan view.

In the forming of the partition wall (S300), the partition wall PW may be formed on the pixel defining layer PDL. The partition wall PW may be deposited to have a multi-layered structure. For example, the first partition wall layer PW1 and the second partition wall layer PW2 may be deposited on the pixel defining layer PDL based on the third direction DR3.

The first partition wall layer PW1 may include aluminum (Al). According to an embodiment, the second partition wall layer PW2 may include titanium (Ti). However, the disclosure is not limited thereto.

In the forming of the partition wall (S300), after the first partition wall layer PW1 and the second partition wall layer PW2 are deposited, considering the material of each layer, an etching process may be performed on the first partition wall layer PW1 and the second partition wall layer PW2.

The first partition wall layer PW1 may be etched relatively deeper than the second partition wall layer PW2. The second partition wall layer PW2 may be etched to protrude further from the edge than the first partition wall layer PW1. The second partition wall layer PW2 may be etched to form a tip structure. According to an embodiment, a side surface of the first partition wall layer PW1 may form an inclined surface. For example, the cross-section of the first partition wall layer PW1 may have a trapezoidal shape that gradually becomes narrower from the bottom to the top (for example, in the third direction DR3). However, the disclosure is not limited thereto. The cross section of the first partition wall layer PW1 may have a rectangular or square shape.

Referring to FIG. 10, in the forming of the light emitting part (S400), the light emitting part EL may be patterned (for example, deposited). The light emitting part EL may be deposited to be formed between the partition walls PW. When depositing the light emitting part EL, the upper light emitting part UEL may also be formed in a same deposition process. For example, the upper light emitting part UEL may be formed on the second partition wall layer PW2.

The light emitting part EL may be deposited on the first electrode ELT1 between the pixel defining layer PDL and the first partition wall layer PW1. The light emitting part EL may cover at least a portion of the pixel defining layer PDL and at least a portion of a side surface of the first partition wall layer PW1.

The upper light emitting part UEL may be deposited on the second partition wall layer PW2. The upper light emitting part UEL may cover at least a portion of the second partition wall layer PW2. The upper light emitting part UEL may expose at least a portion of the second partition wall layer PW2.

In the forming of the second electrode (S500), the second electrode ELT2 may be deposited on the light emitting part EL. The second electrode ELT2 may be deposited to be form between the partition walls PW. When forming the second electrode ELT2, the upper second electrode UELT2 may also be formed in a same deposition process.

The second electrode ELT2 may be deposited on the light emitting part EL between first partition wall layers PW1. The second electrode ELT2 may cover at least a portion of the pixel defining layer PDL and at least a portion of the side surface of the first partition wall layer PW1.

The upper second electrode UELT2 may be deposited on the second partition wall layer PW2. The upper second electrode UELT2 may be deposited on the upper light emitting part UEL. The upper second electrode UELT2 may cover at least a portion of the upper light emitting part UEL. The upper light emitting part UEL may expose at least a portion of the second partition wall layer PW2.

According to an embodiment, after the second electrode ELT2 is formed, the forming of the protective structure (S600) may be performed to manufacture the protective structure 1000. The forming of the protective structure (S600) may include forming the first protective layer L1 and forming the second protective layer L2.

Referring to FIG. 11, the forming of the protective structure (S600) may include depositing a first base protective layer (S601), depositing a second base protective layer (S603), disposing a photoresist (S605), and etching the first base protective layer and the second base protective layer (S607).

Referring to FIG. 12, in the depositing of the first base protective layer (S601), a first base protective layer B_L1 may be deposited. The first base protective layer B_L1 may be deposited to entirely cover the partition wall PW and the second electrode ELT2. For example, the first base protective layer B_L1 may entirely cover the first partition wall layer PW1, the second partition wall layer PW2, and the second electrode ELT2. In the disclosure, the first base protective layer B_L1 may be the first protective layer L1 before being etched, and the first base protective layer B_L1 and the first protective layer L1 may include a same material. For example, the first base protective layer B_L1 may include at least one of silicon nitride (SiNₓ) and silicon oxide (SiOₓ).

The first base protective layer B_L1 may be deposited to have a thickness in a range of about 5000 Å to about 7000 Å. The first base protective layer B_L1 may be deposited through a CVD process. Experimentally, when depositing the first base protective layer B_L1 through a CVD process, due to material properties of silicon nitride (SiNₓ) and silicon oxide (SiOₓ), at least a portion of a surface (for example, top surface) of the first base protective layer B_L1 may be bent (for example, folded) to form the opening H. As at least a portion of a surface (for example, top surface) of the first base protective layer B_L1 is bent, the area A1 where the surfaces of the first base protective layer B_L1 contact with each other may be formed. As a surface of the first base protective layer B_L1 is bent, the discontinuous surface (for example, the seam area) may be formed. The area A1 where the surfaces of the first base protective layer B_L1 contact with each other may provide a path through which impurities (for example, moisture) may penetrate into the display device DD.

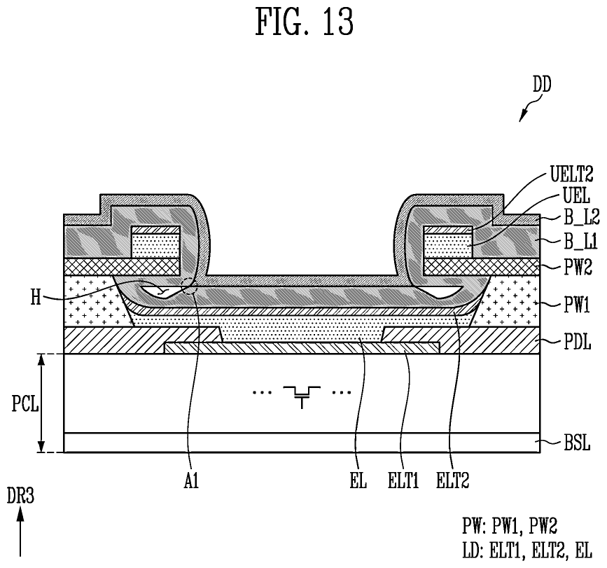

Referring to FIG. 13, in the depositing of the second base protective layer (S603), the second base protective layer B_L2 may be deposited. The second base protective layer B_L2 may be deposited on the first base protective layer B_L1. The second base protective layer B_L2 may be deposited so that the first base protective layer B_L1 is not exposed. The second base protective layer B_L2 may be the second protective layer L2 before being etched, and the second base protective layer B_L2 and the second protective layer L2 may include a same material. For example, the second base protective layer B_L2 may include various materials capable of forming an amorphous thin film layer. For example, the second base protective layer B_L2 may include an amorphous material. For example, the second base protective layer B_L2 may include at least one of amorphous silicon, silicon carbide (SiC), and silicon nitride hydrogen (SiNₓH_{y}).

As the second base protective layer B_L2 includes an amorphous material, when depositing the second base protective layer B_L2, the second base protective layer B_L2 may not be bent. Accordingly, the second base protective layer B_L2 may not form an opening.

The second base protective layer B_L2 may be deposited to have a thickness thinner than a thickness of the first base protective layer B_L1. For example, the second base protective layer B_L2 may be deposited to have a thickness in a range of about 500 Å to about 1500 Å.

The second base protective layer B_L2 may entirely cover a surface of the first base protective layer B_L1 except for the discontinuous surface. For example, the second base protective layer B_L2 may not contact with the opening H defined by the first base protective layer B_L1.

The second base protective layer B_L2 may cover the area A1 where the surfaces of the first base protective layer B_L1 contact with each other. As the second base protective layer B_L2 covers the area A1 where the surfaces of the first base protective layer B_L1 contact with each other, the path through which moisture may penetrate into the display device DD can be blocked, and the risk of moisture penetrating into the display device DD may be reduced.

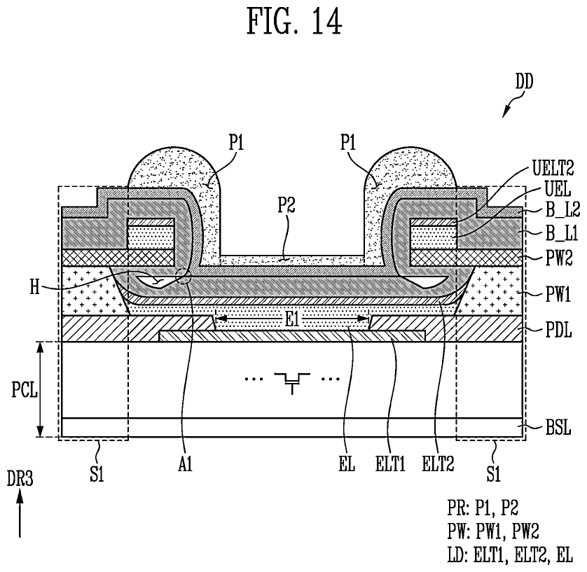

Referring to FIG. 14, in the disposing of the photoresist (S605), a photoresist PR may be disposed on the second base protective layer B_L2. The photoresist PR may expose at least a portion of the second base protective layer B_L2. The photoresist PR may not be disposed on at least a portion of the second base protective layer B_L2. For example, in an area where the second partition wall layer PW2 is disposed, in case that an area that does not overlap with the upper light emitting part UEL or the upper second electrode UELT2 in a plan view is defined as a partition wall central area S1, the photoresist PR may not be disposed on at least a portion of the partition wall central area S1. For example, the photoresist PR may not overlap at least a portion of the partition wall central region S1 in a plan view.

The photoresist PR may include a first portion P1 and a second portion P2 having different thicknesses. The first portion P1 may be a portion of the photoresist PR that overlaps the pixel defining layer PDL in a plan view. The second portion P2 may be the remaining portion of the photoresist PR that does not overlap the pixel defining layer PDL in a plan view.

The photoresist PR may be deposited so that the first portion P1 has a thickness greater than a thickness of the second portion P2. The thickness of the first portion P1 may be the thickest thickness among the thickness of the photoresist PR that simultaneously overlaps the pixel defining layer PDL and the upper light emitting part UEL. The thickness of the second portion P2 may be the thickest thickness among the thickness of the photoresist PR that do not overlap the pixel defining layer PDL in a plan view. Since the first portion P1 is thicker than the second portion P2, the second portion P2 may be exposed to a greater amount of light than the first portion P1.

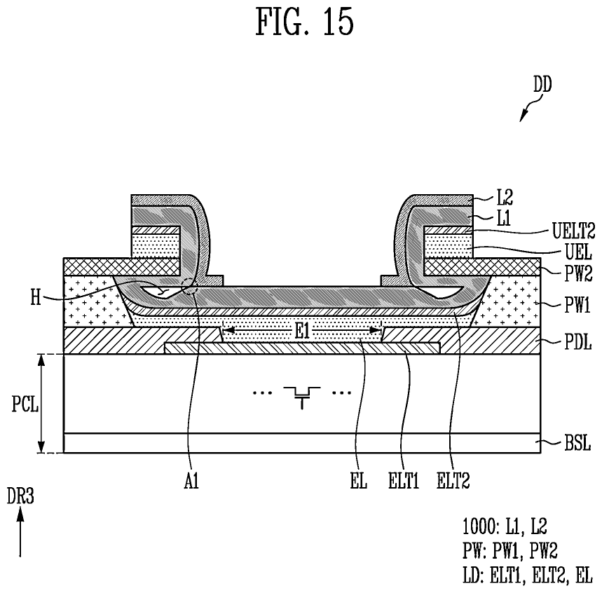

Referring to FIG. 15, in the etching of the first base protective layer and the second base protective layer (S607), at least a portion of each of the first base protective layer B_L1 and the second base protective layer B_L2 may be etched to form the first protective layer L1 and a second protective layer L2. In the etching of the first base protective layer and the second base protective layer (S607), the photoresist PR may be removed.

For example, in an area overlapping the partition wall central area S1 where the photoresist PR is not disposed, the first base protective layer B_L1 and the second base protective layer B_L2 may all be etched. In an area overlapping the second portion P2 of the photoresist PR deposited thinner than the first portion P1 of the photoresist PR, among the first base protective layer B_L1 and the second base protective layer B_L2, the second base protective layer B_L2 may be etched and the first base protective layer B_L1 may not be etched. However, the disclosure is not limited thereto. Depending on the thickness of the second portion P2, a portion of the first base protective layer B_L1 may be etched even in an area overlapping the second portion P2. The first base protective layer B_L1 and the second base protective layer B_L2 overlapping the first portion P1 of the photoresist PR may not be etched.

As the second base protective layer B_L2 is etched in the area overlapping the second portion P2 of the photoresist PR, the emission area E1 may be formed. In case that the second base protective layer B_L2 includes amorphous silicon, the second base protective layer B_L2 may absorb light. However, as the second base protection layer B_L2 is removed from an area that does not overlap the pixel defining layer PDL, the emission area E1 where light is emitted to the outside of the display device DD may be secured.

According to the method of manufacturing the display device DD of the disclosure, the photoresist PR for forming the second protective layer L2 may not be additionally disposed. For example, after the first base protective layer B_L1 and the second base protective layer B_L2 are deposited, the photoresist PR may be disposed, and the second protective layer L2 may be formed through an etching process. Therefore, the same number of photoresists PR as conventional may be used, and no additional photoresists PR may be used.

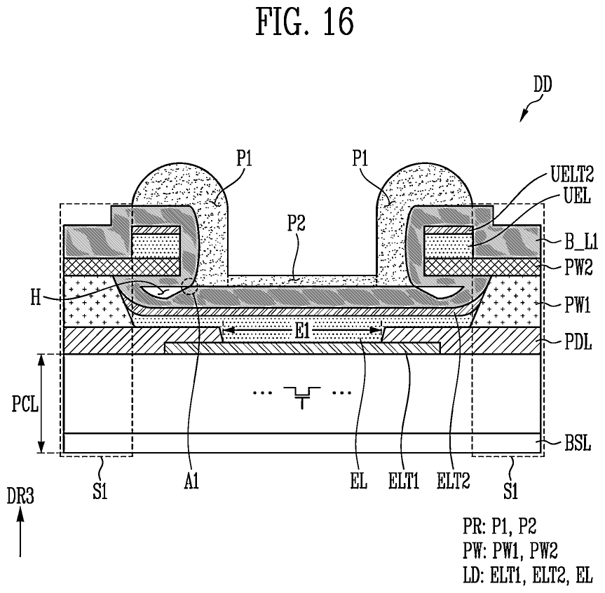

FIG. 16 is a schematic cross-sectional view schematically illustrating a method of manufacturing a display device according to an embodiment in each process step. Hereinafter, the method of manufacturing the display device according to an embodiment will be described with reference to FIGS. 6 and 16.

The method of manufacturing the display device DD according to the embodiment may have a difference that the photoresist PR is disposed before the second base protective layer B_L2 is deposited. For example, the depositing of the second base protective layer (S603) may be performed after the disposing of the photoresist (S605).

The photoresist PR may be disposed on the first base protective layer B_L1. The photoresist PR may be in contact with at least a portion of the first base protective layer B_L1.

The photoresist PR may not be disposed on at least a portion of the partition wall central area S1. For example, the photoresist PR may not overlap at least a portion of the partition wall central area S1 in a plan view.

Referring to FIGS. 6 and 16, at least a portion of the first base protective layer B_L1 may be etched to form the first protective layer L1. In the etching of the first base protective layer B_L1, the photoresist PR may be removed.

In the area overlapping the partition wall central area S1 where the photoresist PR is not disposed, the entire first base protective layer B_L1 may be etched. The first base protective layer B_L1 may be etched relatively less in the area overlapping the second portion P2 of the photoresist PR than in the area overlapping the first portion P1 of the photoresist PR in a plan view. Since the first base protective layer B_L1 is etched less in the area overlapping the second portion P2, the light emitting part EL may not be exposed.

After the first base protective layer B_L1 is etched, in the depositing of the second base protective layer (S603), the second base protective layer B_L2 may be deposited. The second base protective layer B_L2 may be deposited on the first protective layer L1. The second base protective layer B_L2 may entirely cover the first protective layer L1. The second base protective layer B_L2 may be deposited so that the first protective layer L1 is not exposed. The second base protective layer B_L2 may entirely overlap the light emitting part EL in a plan view.

The second base protective layer B_L2 may include silicon nitride hydrogen (SiNₓH_{y}). According to an embodiment, in case that the second base protective layer B_L2 includes silicon nitride hydrogen (SiNₓH_{y}), the second base protective layer B_L2 may be deposited at a temperature lower than or equal to about 100° C.

According to an embodiment, the second base protective layer B_L2 may not be removed from an area that does not overlap the pixel defining layer PDL in a plan view. Experimentally, in case that the second base protective layer B_L2 includes silicon nitride hydrogen (SiNₓH_{y}), compared to an embodiment that the second base protective layer B_L2 includes amorphous silicon, the second base protection layer B_L2 may have a relatively low extinction coefficient. Accordingly, even in case that the second protective layer L2 is deposited to cover the light emitting part EL, light emitted from the light emitting part EL may not be blocked by the second protective layer L2.

According to an embodiment, the process of etching the second base protective layer B_L2 may not be performed, and the second base protective layer B_L2 may be used as the second protective layer L2.

In the above, only a cross-section of one of the first to third sub-pixels SPX1 to SPX3 is shown, and the method of manufacturing the display device DD is explained. However, the method of manufacturing the display device DD described above may be used to manufacture each of the first sub-pixel SPX1, the second sub-pixel SPX2, and the third sub-pixel SPX3. For example, the protective structure 1000 may be formed in areas where the first sub-pixel SPX1, the second sub-pixel SPX2, and the third sub-pixel SPX3 are disposed. However, the disclosure is not limited thereto.

According to an embodiment, some sub-pixels may not include the second protective layer L2. For example, among the areas where the first sub-pixel SPX1, the second sub-pixel SPX2, and the third sub-pixel SPX3 are disposed, the protective structure 1000 may be formed only in an area where the last formed pixel (for example, the third sub-pixel SPX3) is disposed. For example, the first sub-pixel SPX1 and the second sub-pixel SPX2 may not include the second protective layer L2, and the third sub-pixel SPX3 may include the second protective layer L2.

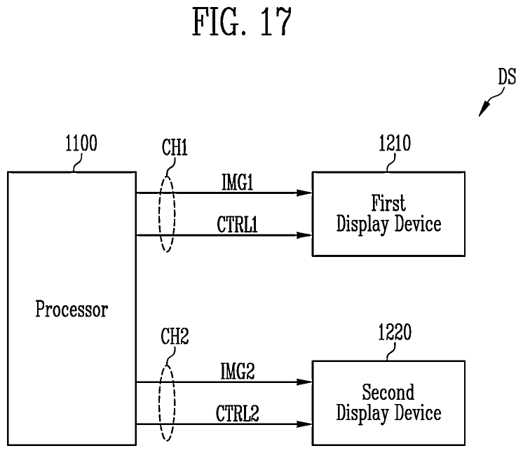

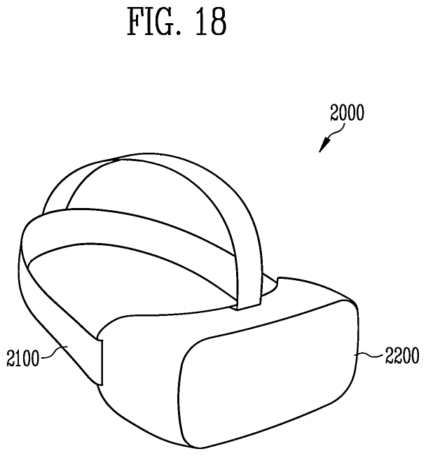

Hereinafter, a display system DS to which the display device DD can be applied will be described with reference to FIGS. 17 and 18.

FIG. 17 is a schematic block diagram of a display system according to an embodiment. FIG. 18 is a schematic perspective view of the display system of FIG. 17 according to an embodiment.

Referring to FIG. 17, the display system DS may include a processor 1100 and one or more display devices 1210 and 1220.

The processor 1100 may perform various tasks and calculations. In embodiments, the processor 1100 may include an application processor, a graphics processor, a microprocessor, a central processing unit (CPU), or the like. The processor 1100 may be connected to and control other components of the display system DS through a bus system.

FIG. 17 schematically shows an embodiment in which the display system DS includes first and second display devices 1210 and 1220. The processor 1100 may be connected to the first display device 1210 through a first channel CH1 and may be connected to the second display device 1220 through a second channel CH2.

The processor 1100 may transmit first image data IMG1 and a first control signal CTRL1 to the first display device 1210 through the first channel CH1. The first display device 1210 may display an image based on the first image data IMG1 and the first control signal CTRL1. The first display device 1210 may be configured similarly to the display device DD described with reference to FIG. 1.

The processor 1100 may transmit second image data IMG2 and a second control signal CTRL2 to the second display device 1220 through the second channel CH2. The second display device 1220 may display an image based on the second image data IMG2 and the second control signal CTRL2. The second display device 1220 may be configured similarly to the display device DD described with reference to FIG. 1.

The display system DS may include a computing system that provides an image display function such as a portable computer, a mobile phone, a smart phone, a tablet personal computer, a smart watch, a watch phone, a portable multimedia player (PMP), a navigation, and an ultra mobile personal computer (UMPC). The display system DS may include at least one of a head-mounted display (HMD), a virtual reality (VR) device, a mixed reality (MR) device, and an augmented reality (AR) device.

Referring to FIG. 18, the display system DS of FIG. 17 may be applied to a head-mounted display device 2000. The head-mounted display device 2000 may be a wearable electronic device that can be worn on a user's head.

The head-mounted display device 2000 may include a head mounting band 2100 and a display device storage case 2200. The head mounting band 2100 may be connected to the display device storage case 2200. The head mounting band 2100 may include a horizontal band and/or a vertical band for fixing the head-mounted display device 2000 to the user's head. The horizontal band may be configured to surround the side of the user's head, and the vertical band may be configured to surround the top of the user's head. However, the disclosure is not limited thereto. For example, the head mounting band 2100 may be implemented in the form of glasses frames, helmets, or the like.

The display device storage case 2200 may accommodate the first and second display devices 1210 and 1220 of FIG. 17. The display device storage case 2200 may further accommodate the processor 1100 of FIG. 17.

According to the embodiments of the disclosure, a display device which can reduce the risk of impurities penetrating from outside and has a protective structure that can stably cover a partition wall, and a method of manufacturing the same is provided.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a partition wall disposed on a base layer;
a light emitting part disposed adjacent to the partition wall;
an upper light emitting part disposed on the partition wall;
a first protective layer disposed on the light emitting part; and
a second protective layer disposed on the first protective layer, wherein
the first protective layer entirely overlaps the light emitting part in a plan view, and
the second protective layer does not overlap at least a portion of the light emitting part and at least a portion of the first protective layer in a plan view.

2. The display device of claim 1, wherein
the first protective layer includes at least one of silicon nitride and silicon oxide, and
the second protective layer includes an amorphous material.

3. The display device of claim 2, wherein the second protective layer includes at least one of amorphous silicon, silicon carbide, and silicon nitride hydrogen.

4. The display device of claim 1, further comprising:
a pixel defining layer disposed on the base layer, wherein
the partition wall is disposed on the pixel defining layer,
the light emitting part includes an area that does not overlap the second protective layer and the pixel defining layer in a plan view, and
an end of each of the upper light emitting part, the first protective layer, and the second protective layer coincides with each other.

5. The display device of claim 1, wherein
at least a portion of the first protective layer is bent to form an opening, and
the opening and the second protective layer overlap each other in a plan view.

6. The display device of claim 5, wherein the opening formed by the first protective layer and the second protective layer are in contact with each other.

7. The display device of claim 4, wherein
the partition wall includes a first partition wall layer disposed on the pixel defining layer and a second partition wall layer disposed on the first partition wall layer, and
the second partition wall layer protrudes further outward than the first partition wall layer.

8. The display device of claim 7, wherein
the first partition wall layer includes aluminum (Al), and
the second partition wall layer includes titanium (Ti).

9. The display device of claim 7, wherein the first protective layer and the second protective layer expose at least a portion of the second partition wall layer.

10. The display device of claim 1, wherein
a thickness of the first protective layer is in a range of about 5000 Å to about 7000 Å, and
a thickness of the second protective layer is less than the thickness of the first protective layer.

11. A display device comprising:
a partition wall disposed on a base layer;
a light emitting part disposed adjacent to the partition wall;
an upper light emitting part disposed on the partition wall;
a first protective layer disposed on the light emitting part; and
a second protective layer disposed on the first protective layer, wherein
the first protective layer entirely overlaps the light emitting part in a plan view, and
the second protective layer includes silicon nitride hydrogen.

12. The display device of claim 11, wherein the second protective layer entirely overlaps the light emitting part in a plan view.

13. The display device of claim 12, wherein
a thickness of the first protective layer is in a range of about 5000 Å to about 7000 Å, and
a thickness of the second protective layer is less than the thickness of the first protective layer.

14. A method of manufacturing a display device comprising:
forming a partition wall on a base layer;
forming a light emitting part adjacent to the partition wall and an upper light emitting part on the partition wall; and
forming a protective structure on the light emitting part, wherein
the forming of the protective structure on the light emitting part includes:
forming a first protective layer on the light emitting part; and
forming a second protective layer on the first protective layer,
the forming of the first protective layer on the light emitting part includes depositing a first base protective layer on the light emitting part so that a surface of the first base protective layer is bent to form an opening, and
the forming of the second protective layer on the first protective layer includes depositing a second base protective layer including an amorphous material.

15. The method of claim 14, wherein
the first base protective layer includes at least one of silicon nitride and silicon oxide,
the second base protective layer includes at least one of amorphous silicon, silicon carbide, and silicon nitride hydrogen, and
the forming of the first protective layer on the light emitting part includes depositing the first base protective layer through a CVD (chemical vapor deposition) process.

16. The method of claim 15, wherein
in the forming of the protective structure on the light emitting part, a photoresist is disposed on the second base protective layer, and the first base protective layer and the second base protective layer are etched,
the forming of the second protective layer on the first protective layer includes depositing the second base protective layer to cover a surface of the first base protective layer except for the opening, and
the photoresist includes a first portion and a second portion having different thicknesses, and is disposed on at least a portion of the second base protective layer.

17. The method of claim 16, further comprising:
forming a pixel defining layer on the base layer, wherein
the forming of the partition wall on the base layer includes forming the partition wall on the pixel defining layer,
the first portion overlaps the upper light emitting part in a plan view, and
the second portion does not overlap the pixel defining layer in a plan view.

18. The method of claim 17, wherein
the first base protective layer and the second base protective layer overlapping the first portion in a plan view are not etched, and
the second base protective layer overlapping the second portion in a plan view is etched.

19. The method of claim 14, wherein
the first base protective layer includes at least one of silicon nitride and silicon oxide,
the second base protective layer includes silicon nitride hydrogen, and
in the forming of the protective structure on the light emitting part, a photoresist is disposed on the first base protective layer so as to contact the first base protective layer.

20. The method of claim 19, wherein the second base protective layer is deposited to entirely overlap the light emitting part in a plan view.
